(19) United States
(12) Patent Application Publication
(10) Pub. No.: US 2024/0258267 A1
(43) Pub. Date: Aug. 1, 2024

(54) METHOD OF MANUFACTURING SEMICONDUCTOR DEVICE

(71) Applicant: Mitsubishi Electric Corporation, Tokyo (JP)

(72) Inventors: Naoki YOSHIMATSU, Tokyo (JP); Norikazu SAKAI, Tokyo (JP); Hiroyuki MASUMOTO, Tokyo (JP)

(73) Assignee: Mitsubishi Electric Corporation, Tokyo (JP)

(21) Appl. No.: 18/498,836

(22) Filed: Oct. 31, 2023

(30) Foreign Application Priority Data
Jan. 27, 2023 (JP) 2023-010742

(51) Int. Cl. H01L 23/00

(52) U.S. Cl. CPC H01L 24/83; H01L 24/29; H01L 24/32; H01L 24/45; H01L 24/48; H01L 24/73; H01L 2224/29111; H01L 2224/29113; H01L 2224/32245; H01L 2224/45124; H01L 2224/48175; H01L 2224/73215; H01L 2224/73265; H01L 2224/83097; H01L 2224/83098; H01L 2924/13055; H01L 2924/13091; H01L 2924/181

(57) ABSTRACT

A method of manufacturing a semiconductor device includes a transfer molding step and a mold package mounting step. The mold package mounting step includes steps of disposing a semiconductor module on an upper surface of a metal base plate with a second bonding member therebetween, heating the metal base plate, the second bonding member, and the semiconductor module to melt the second bonding member, and then cooling the metal base plate, the second bonding member, and the semiconductor module to cure the second bonding member. During the cooling of the metal base plate, the second bonding member, and the semiconductor module, a difference between an upper surface temperature of the metal base plate and a lower surface temperature of a first metal plate at a solid phase line of the second bonding member is 5° C. or less.

### BACKGROUND OF THE INVENTION

### Field of the Invention

The present disclosure relates to a method of manufacturing a semiconductor device.

### Description of the Background Art

For example, Japanese Patent Application Laid-Open No. 2021-111765 proposes a technique for avoiding a defect such as peeling of a resin insulating layer (corresponding to an insulating layer) incorporated in a semiconductor device due to high temperature in a reflow process at the time of solder bonding by setting a thickness dimension of a copper plate fixed to a lower surface of a heat spreader with the resin insulating layer therebetween to a value of 0.3 mm or more and not exceeding a thickness dimension of the heat spreader.

In the technique described in Japanese Patent Application Laid-Open No. 2021-111765, in order to suppress the peeling of the resin insulating layer, the thickness of the copper plate integrated with the resin insulating layer is increased to improve rigidity of the copper plate. An electrolytic copper foil is typically adopted as the copper plate in order to enhance the effect of suppressing the peeling of the resin insulating layer.

However, an attempt to increase the thickness of the electrolytic copper foil results in an increase in manufacturing cost. When a rolled copper plate is adopted instead of the electrolytic copper foil, adhesion to the resin insulating layer is lower than that of adopting the electrolytic copper foil. Therefore, in order to improve the adhesion to the resin insulating layer, it is necessary to perform another process such as roughening of a surface of the rolled copper plate, which results in an increase in manufacturing cost.

In addition, in a structure adopting a ceramic insulating substrate as the insulating layer, stress on the ceramic insulating substrate generated at the time of bonding a semiconductor module and a metal base plate becomes a problem.

### SUMMARY

An object of the present disclosure is to provide a technique that enables reduction of stress on an insulating layer generated at the time of bonding a semiconductor module and a metal base plate without improving rigidity of a metal plate bonded to a lower surface of the insulating layer.

A method of manufacturing a semiconductor device according to the present disclosure includes: a step (a) of manufacturing a semiconductor module by sealing, with a mold resin, a first metal plate, an insulating layer bonded to a lower surface of the first metal plate, a second metal plate bonded to a lower surface of the insulating layer, and a semiconductor element mounted on an upper surface of the first metal plate with a first bonding member between the semiconductor element and the first metal plate in a state in which a lower surface of the second metal plate is exposed; and a step (b) of mounting the semiconductor module on a metal base plate by bonding the lower surface of the second metal plate to an upper surface of the metal base plate by a second bonding member having a melting point lower than a melting point of the first bonding member. The step (b) includes steps of disposing the semiconductor module on the upper surface of the metal base plate with the second bonding member between the semiconductor module and the metal base plate, heating the metal base plate, the second bonding member, and the semiconductor module to melt the second bonding member, and then cooling the metal base plate, the second bonding member, and the semiconductor module to cure the second bonding member. During the cooling of the metal base plate, the second bonding member, and the semiconductor module, a difference between an upper surface temperature of the metal base plate and a lower surface temperature of the first metal plate at a solid phase line of the second bonding member is 5° C. or less.

It is possible to reduce stress on the insulating layer generated at the time of bonding the semiconductor module and the metal base plate without improving the rigidity of the second metal plate bonded to the lower surface of the insulating layer.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first preferred embodiment;

FIG. 2 is an upper view of the semiconductor device according to the first preferred embodiment;

FIGS. 3 to 8 are cross-sectional views each illustrating a part of a method of manufacturing the semiconductor device according to the first preferred embodiment;

FIG. 9 is a graph illustrating a difference between an upper surface temperature of a metal base plate and a lower surface temperature of a first metal plate during cooling in the first preferred embodiment;

FIG. 10 is a graph illustrating temperature profiles of the metal base plate and the first metal plate during rapid cooling in the first preferred embodiment;

FIG. 11 is a graph illustrating a dielectric withstand voltage after the rapid cooling in the first preferred embodiment;

FIG. 12 is a graph illustrating temperature profiles of the metal base plate and the first metal plate during slow cooling in the first preferred embodiment;

FIG. 13 is a graph illustrating a dielectric withstand voltage after the slow cooling in the first preferred embodiment;

FIG. 14 is a cross-sectional view of a semiconductor device according to a second preferred embodiment;

FIG. 15 is a cross-sectional view of a semiconductor device according to a third preferred embodiment;

FIG. 16 is a graph illustrating a difference between an upper surface temperature of a metal base plate and a lower surface temperature of a first metal plate during cooling in the third preferred embodiment; and

FIG. 17 is a cross-sectional view illustrating a part of a method of manufacturing the semiconductor device according to a modification of the third preferred embodiment.

### DESCRIPTION OF THE PREFERRED EMBODIMENTS

### First Preferred Embodiment

(Structure of semiconductor device)

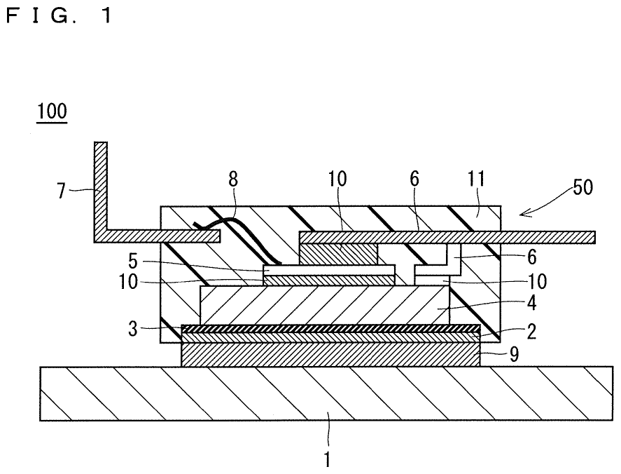

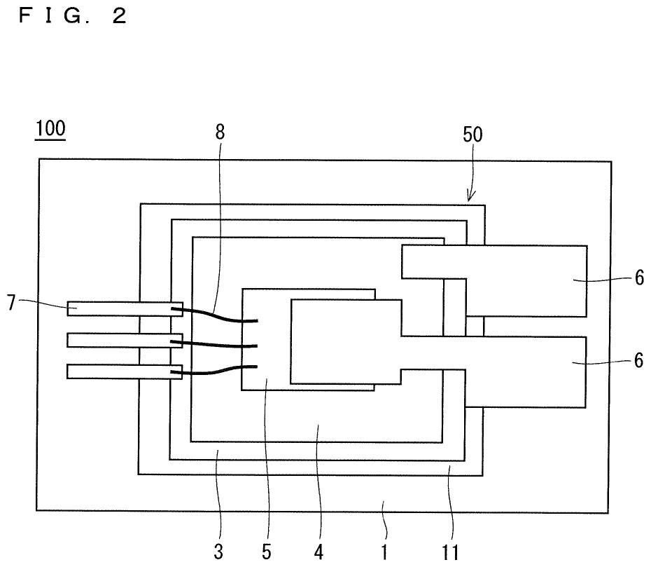

A first preferred embodiment will be described below with reference to the drawings. FIG. 1 is a cross-sectional view of a semiconductor device 100 according to the first preferred embodiment. FIG. 2 is an upper view of the semiconductor device 100 according to the first preferred embodiment. In FIG. 2, a portion of a mold resin 11 above main terminals 6 and signal terminals 7 is not illustrated in order to make an internal structure easily viewable.

As illustrated in FIGS. 1 and 2, the semiconductor device 100 includes a semiconductor module 50 and a metal base plate 1.

The semiconductor module 50 includes a first metal plate 4, a resin insulating layer 3 (corresponding to an insulating layer), a second metal plate 2, a semiconductor element 5, the plurality of (for example, two) main terminals 6, the plurality of (for example, three) signal terminals 7, and the mold resin 11.

The first metal plate 4 is bonded to an upper surface of the resin insulating layer 3. The second metal plate 2 is bonded to a lower surface of the resin insulating layer 3. The first metal plate 4 and the second metal plate 2 are desirably formed of copper, but may be formed of metal other than copper.

The semiconductor element 5 is mounted on an upper surface of the first metal plate 4 with a first bonding member 10 therebetween. Although only one semiconductor element 5 is illustrated in FIGS. 1 and 2, the number of semiconductor elements 5 is not limited to one and may be plural.

The semiconductor element 5 is, for example, an insulated gate bipolar transistor (IGBT) or a metal oxide semiconductor field effect transistor (MOSFET). The semiconductor element 5 may include a free wheeling diode (FWD) electrically connected to the semiconductor element 5. The semiconductor element 5 is made of silicon or a wide band gap semiconductor material. The wide band gap semiconductor material is silicon carbide, a gallium nitride-based semiconductor material, diamond, and the like.

One end of one of the main terminals 6 is bonded to an upper-surface electrode of the semiconductor element 5 with the first bonding member 10 therebetween. One end of the other main terminal 6 is bonded to the upper surface of the first metal plate 4 with the first bonding member 10 therebetween. One end of each of the three signal terminals 7 is bonded to a corresponding signal pad (not illustrated) on an upper surface of the semiconductor element 5 by an aluminum wire 8. The first bonding member 10 is solder.

The mold resin 11 seals the first metal plate 4, the resin insulating layer 3, the second metal plate 2, the semiconductor element 5, one end sides of the two main terminals 6, and one end sides of the three signal terminals 7 in a state in which a lower surface of the second metal plate 2 is exposed. Therefore, the other end sides of the two main terminals 6 and the other end sides of the three signal terminals 7 protrude from the mold resin 11. The mold resin 11 is a thermosetting resin such as an epoxy resin.

The lower surface of the second metal plate 2 is bonded to an upper surface of the metal base plate 1 with a second bonding member 9 therebetween, so that the semiconductor module 50 and the metal base plate 1 are bonded together. The second bonding member 9 has a melting point lower than that of the first bonding member 10.

Specifically, the second bonding member 9 is tin solder containing bismuth.

<Method of manufacturing semiconductor device>

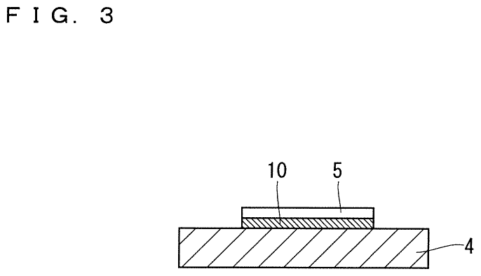

Next, an outline of a method of manufacturing the semiconductor device 100 will be described with reference to FIGS. 3 to 8. FIGS. 3 to 8 are cross-sectional views each illustrating a part of the method of manufacturing the semiconductor device 100 according to the first preferred embodiment.

First, as illustrated in FIG. 3, a die bonding step is performed in which the semiconductor element 5 is mounted on the upper surface of the first metal plate 4 with the first bonding member 10 therebetween.

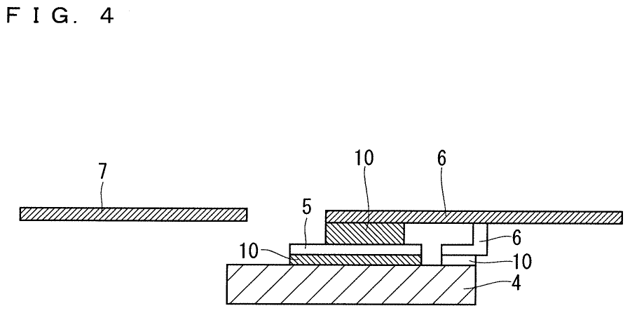

Next, as illustrated in FIG. 4, a frame bonding step is performed in which the semiconductor element 5 and the main terminal 6 are bonded together by the first bonding member 10 and the first metal plate 4 and the main terminal 6 are bonded together by the first bonding member 10.

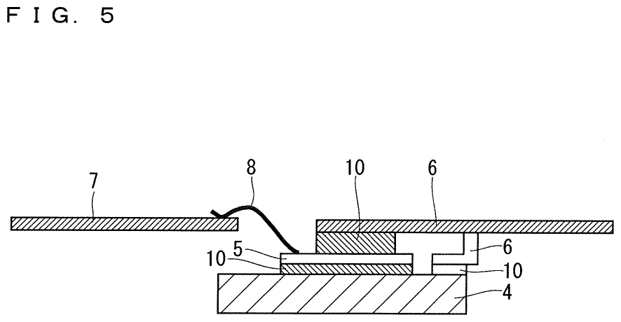

Next, as illustrated in FIG. 5, a wire bonding step is performed in which the three signal pads on the semiconductor element 5 and the three signal terminals 7 are individually connected by the aluminum wires 8.

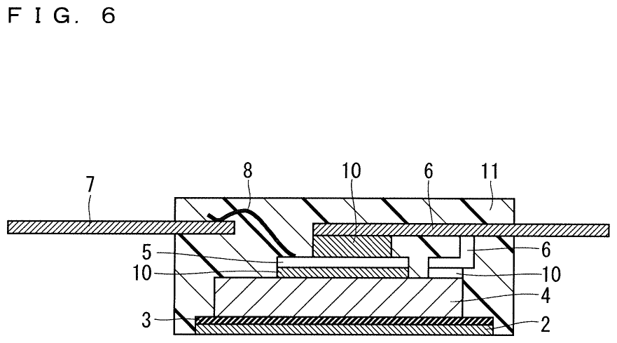

Next, as illustrated in FIG. 6, a transfer molding step is performed in which an insulating sheet in which the resin insulating layer 3 in a semi-cured state and the second metal plate 2 are integrated and the wire bonding completed product are set in a cavity of a metal mold (not illustrated) heated to, for example, 180ºC, the molten mold resin 11 is poured into the cavity, and pressure is applied to the molten mold resin 11 to cure the molten mold resin 11 and also cure the semi-cured resin insulating layer 3.

The transfer molding step corresponds to a step (a) of manufacturing the semiconductor module 50 by sealing, with the mold resin 11, the first metal plate 4, the resin insulating layer 3 bonded to a lower surface of the first metal plate 4, the second metal plate 2 bonded to the lower surface of the resin insulating layer 3, and the semiconductor element 5 mounted on the upper surface of the first metal plate 4 with the first bonding member 10 therebetween in a state in which the lower surface of the second metal plate 2 is exposed.

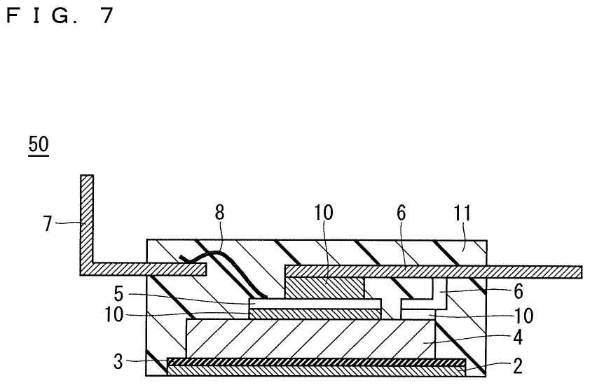

Next, as illustrated in FIG. 7, a lead processing step is performed in which an unnecessary portion of a lead frame including the main terminals 6 and the signal terminals 7 is cut off and the remaining portion is bent into a desired shape. The semiconductor module 50 is manufactured through the steps of FIGS. 3 to 7.

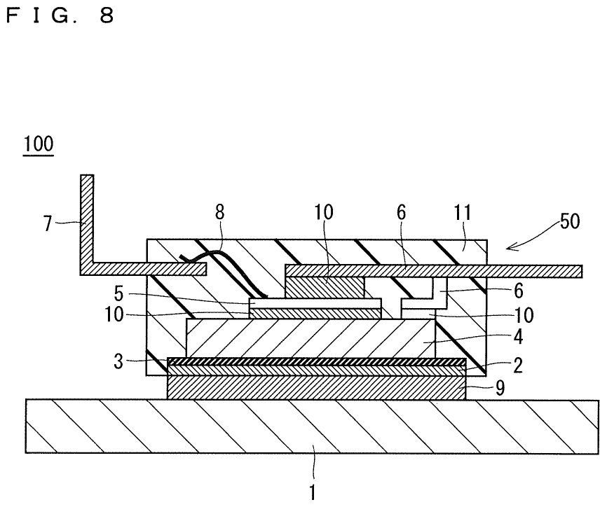

Next, as illustrated in FIG. 8, a mold package mounting step is performed in which the semiconductor module 50 is mounted on the metal base plate 1 by bonding the upper surface of the metal base plate 1 and the lower surface of the second metal plate 2 together by the second bonding member 9.

The mold package mounting step corresponds to a step (b) of mounting the semiconductor module 50 on the metal base plate 1 by bonding the lower surface of the second metal plate 2 to the upper surface of the metal base plate 1 by the second bonding member 9 having a melting point lower than that of the first bonding member 10.

Here, the first bonding member 10 used in the die bonding step and the first bonding member 10 used in the frame bonding step are the same members. Although the first bonding member 10 used in the die bonding step is temporarily remelted by being heated in the frame bonding step, the periphery of this first bonding member 10 is not in a sealed state, and thus there is no particular problem.

However, it is necessary to avoid remelting of the first bonding member 10 in the semiconductor module 50 in the mold package mounting step. Therefore, the second bonding member 9 is required to have a melting point lower than that of the first bonding member 10. This is because the remelting of the first bonding member 10 causes volume expansion of the first bonding member 10, resulting in leakage of the first bonding member to an interface between the mold resin 11 and the first metal plate 4 or the like, or breakage of the mold resin 11 and ejection of the first bonding member 10.

During the mold package mounting step, the second bonding member 9 is cured in a state in which there is a transitional difference between a shrinkage of the metal base plate 1 bonded in a high-temperature state at the time of returning to room temperature and a shrinkage of the first metal plate 4 sealed with the mold resin 11, and shearing stress is applied to the second bonding member 9 and the resin insulating layer 3. This causes a problem of peeling of the resin insulating layer 3. In order to suppress this peeling, temperature control during cooling is required.

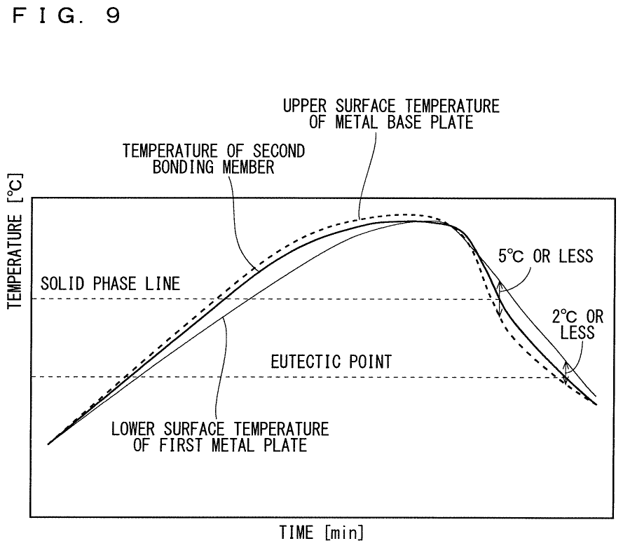

Next, the temperature control during cooling will be described. FIG. 9 is a graph illustrating a difference between an upper surface temperature of the metal base plate 1 and a lower surface temperature of the first metal plate 4 during cooling in the first preferred embodiment.

In the mold package mounting step, a heater block or a cooling block is brought into contact with a lower surface of the metal base plate 1, so that the semiconductor module 50 can be efficiently heated and cooled. However, since the second bonding member 9 and the semiconductor module 50 change in temperature following the metal base plate 1, a temperature difference is generated between the metal base plate 1, and the second bonding member 9 and the semiconductor module 50 during heating and cooling. Therefore, as a heating rate and a cooling rate are higher, and as the semiconductor module 50 has a larger heat capacity, the temperature difference increases. When the temperature difference during cooling increases, shearing stress is generated in the resin insulating layer 3 and the second bonding member 9 as described above. Therefore, as illustrated in FIG. 9, the difference between the upper surface temperature of the metal base plate 1 and the lower surface temperature of the first metal plate 4 at a time when the second bonding member 9 reaches a temperature of a solid phase line during cooling is desirably set to 5° C. or less.

As described above, the second bonding member 9 is the tin solder containing bismuth. When bismuth is added to the tin solder, the melting point changes depending on a proportion of the bismuth. When the bismuth is contained at 58%, the melting point is 139ºC, which is the lowest (eutectic point). Hereinafter, the tin solder containing the bismuth at 58% is also referred to as “Sn-58Bi”.

Regardless of the amount of added bismuth, the second bonding member 9 is completely cured at 139° C. or less because of the eutectic point partly present in the second bonding member 9. Therefore, the difference between the upper surface temperature of the metal base plate 1 and the lower surface temperature of the first metal plate 4 at the cutectic point of 139° ° C. of Sn-58Bi at which the second bonding member 9 is completely cured is desirably set to 2° C. or less. Experimental results have revealed that stress on the resin insulating layer 3 can be reduced by performing such temperature control.

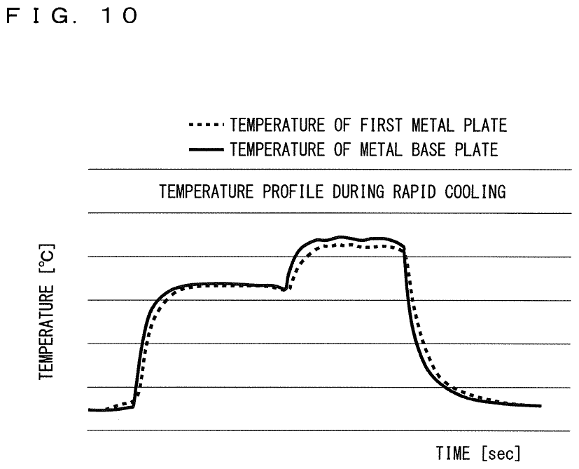

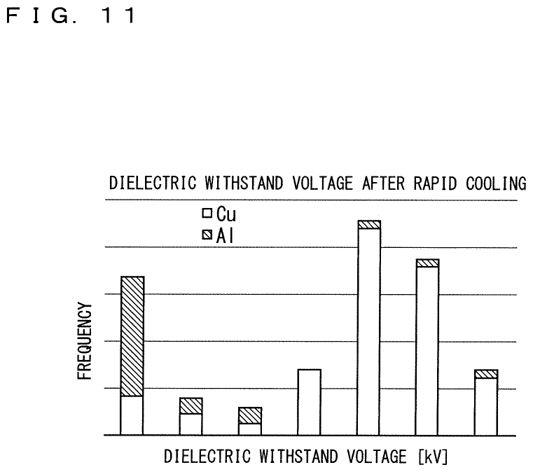

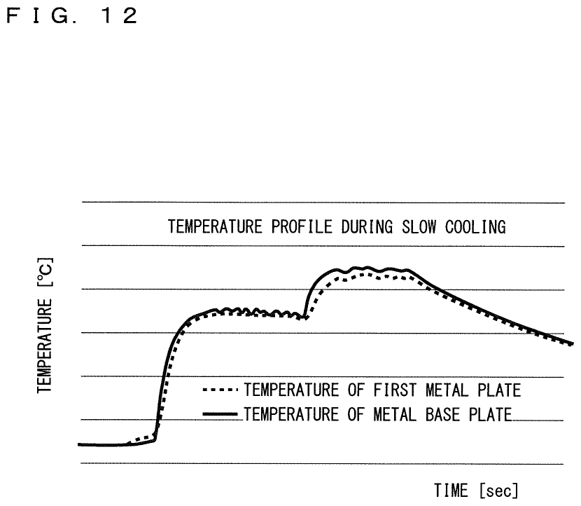

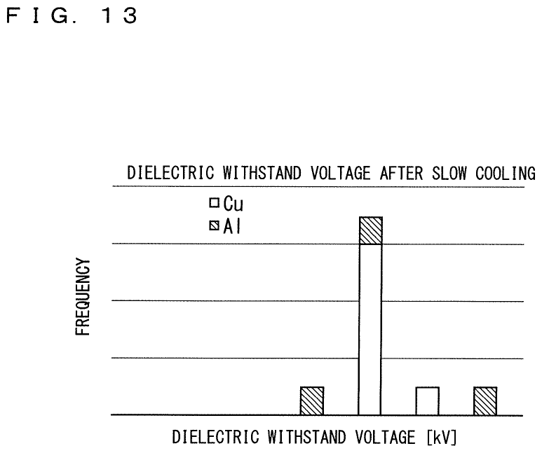

FIGS. 10 to 13 illustrate the experimental results. FIG. 10 is a graph illustrating temperature profiles of the metal base plate 1 and the first metal plate 4 during rapid cooling in the first preferred embodiment. FIG. 11 is a graph illustrating a dielectric withstand voltage after the rapid cooling in the first preferred embodiment. FIG. 12 is a graph illustrating temperature profiles of the metal base plate 1 and the first metal plate 4 during slow cooling in the first preferred embodiment. FIG. 13 is a graph illustrating a dielectric withstand voltage after the slow cooling in the first preferred embodiment.

FIGS. 10 and 12 are plots of the temperatures of the metal base plate 1 and the first metal plate 4 in the mold package mounting step. FIG. 10 illustrates a state in which the metal base plate 1 is brought into contact with a cooling block to be rapidly cooled during cooling, and FIG. 12 illustrates a state in which the metal base plate 1 is brought into contact with nothing to be slowly cooled during cooling.

As illustrated in FIG. 10, the metal base plate 1 has a lower temperature than that of the first metal plate 4 during the rapid cooling, whereas as illustrated in FIG. 12, the temperatures of the metal base plate 1 and the first metal plate 4 are substantially the same during the slow cooling.

FIGS. 11 and 13 illustrate results of measuring the dielectric withstand voltage using several tens of samples of the semiconductor device 100 in order to confirm the soundness of the resin insulating layer 3 in the rapid cooling and the slow cooling. The metal base plate 1 of the semiconductor device 100 used for the samples is formed of aluminum or copper. The horizontal axis represents the dielectric withstand voltage, in which insulation performance becomes higher toward the right, and the vertical axis represents frequency (the number of samples). In FIG. 11, the dielectric withstand voltage varies within a low range although some samples have high dielectric withstand voltages. On the other hand, in FIG. 13, there are only high dielectric withstand voltages.

In order to perform such temperature control, in the first preferred embodiment, the metal base plate 1, the second bonding member 9, and the semiconductor module 50 are cooled by blowing a cooled reducing gas from above the semiconductor module 50 without bringing a heater block or a cooling block into contact with the lower surface of the metal base plate 1 in the mold package mounting step.

Since the semiconductor element 5 is mounted on the upper surface of the first metal plate 4, it is necessary to efficiently dissipate heat generated during an operation of the semiconductor element 5 to the metal base plate 1. Therefore, the heat is spread and dissipated in a large area by the first metal plate 4 before the heat passes through the resin insulating layer 3 having lower thermal conductivity than metal, so that thermal resistance of the entire semiconductor device 100 decreases, and a package having good heat dissipation is obtained.

Furthermore, it is effective that heat generated by the semiconductor element 5 due to a short-time load is absorbed by a heat capacity of the first metal plate 4 immediately below the semiconductor element 5. Therefore, it is necessary for the first metal plate 4 to have a certain thickness, and the thickness of the first metal plate 4 is desirably from 2.5 mm to 4 mm, inclusive. If the thickness exceeds this range, not only thermal resistance of the first metal plate 4 itself increases to deteriorate the heat dissipation, but also a package weight and a manufacturing cost increase.

The resin insulating layer 3 has functions of insulation and heat dissipation, and is desirably thick for insulation, but is desirably thin for heat dissipation. Therefore, it is desirable that the resin insulating layer 3 is made as thin as possible while securing a thickness corresponding to a dielectric withstand voltage required for the package. Since the thickness corresponding to the dielectric withstand voltage includes aged deterioration and a margin, the thickness of the resin insulating layer 3 is desirably from 0.1 mm to 0.25 mm, inclusive. Since the resin insulating layer 3 is vertically sandwiched between the first metal plate 4 and the second metal plate 2, a linear expansion coefficient of the resin insulating layer 3 is desirably as close as possible to copper. A filler content is adjusted so that the linear expansion coefficient of the resin insulating layer 3 is from 10 ppm/K to 20 ppm/K, inclusive. Examples of the filler include boron nitride, aluminum nitride, and aluminum oxide. The filler is used not only for adjusting the linear expansion coefficient but also for improving the thermal conductivity.

A component in which the second metal plate 2 and the resin insulating layer 3 are integrated is referred to as an insulating sheet. A method of manufacturing the insulating sheet includes applying a liquid resin to be the resin insulating layer 3 to the second metal plate 2, and applying pressure thereto while heating them to semi-cure the liquid resin.

The second metal plate 2 functions to hold a shape of the insulating sheet, protect the resin insulating layer 3 after the mold package mounting step, and be bonded to the metal base plate 1. In order to fulfill these functions, adhesion between the second metal plate 2 and the resin insulating layer 3 is necessary. It is suitable and typical to adopt an electrolytic copper foil whose one surface is uneven as the second metal plate 2. However, in a method of manufacturing the electrolytic copper foil, copper deposited on a cathode is processed into a sheet shape by passing electricity through a copper sulfate tank. Thus, a thickness increase results in an increase in manufacturing cost. Therefore, it is desirable to adopt an electrolytic copper foil of 0.25 mm or less as the second metal plate 2.

Similarly to the first metal plate 4, it is necessary for the metal base plate 1 to have a certain thickness in order to spread heat from the semiconductor element 5. Specifically, it is desirable that the metal base plate 1 has a thickness of from 2 mm to 4 mm, inclusive, and is formed of copper, aluminum, or an alloy containing copper or alloy as a main component.

### <Effects>

As described above, the manufacturing method of the first preferred embodiment includes: the transfer molding step of manufacturing the semiconductor module 50 by sealing, with the mold resin 11, the first metal plate 4, the resin insulating layer 3 bonded to the lower surface of the first metal plate 4, the second metal plate 2 bonded to the lower surface of the resin insulating layer 3, and the semiconductor element 5 mounted on the upper surface of the first metal plate 4 with the first bonding member 10 therebetween in a state in which the lower surface of the second metal plate 2 is exposed; and the mold package mounting step of mounting the semiconductor module 50 on the metal base plate 1 by bonding the lower surface of the second metal plate 2 to the upper surface of the metal base plate 1 by the second bonding member 9 having a melting point lower than that of the first bonding member 10. The mold package mounting step includes steps of disposing the semiconductor module 50 on the upper surface of the metal base plate 1 with the second bonding member 9 therebetween, heating the metal base plate 1, the second bonding member 9, and the semiconductor module 50 to melt the second bonding member 9, and then cooling the metal base plate 1, the second bonding member 9, and the semiconductor module 50 to cure the second bonding member 9. During the cooling of the metal base plate 1, the second bonding member 9, and the semiconductor module 50, the difference between the upper surface temperature of the metal base plate 1 and the lower surface temperature of the first metal plate 4 at the solid phase line of the second bonding member 9 is 5° C. or less.

Therefore, it is possible to reduce the stress on the resin insulating layer 3 generated at the time of bonding the semiconductor module 50 and the metal base plate 1 without improving rigidity of the second metal plate 2 bonded to the lower surface of the resin insulating layer 3. This makes it possible to suppress the peeling of the resin insulating layer 3. In addition, durability of a cooling/heating cycle in the semiconductor device 100 is improved, so that long-term reliability of the semiconductor device 100 is improved as well.

The second bonding member 9 is the tin solder containing the bismuth. During the cooling of the metal base plate 1, the second bonding member 9, and the semiconductor module 50, the difference between the upper surface temperature of the metal base plate 1 and the lower surface temperature of the first metal plate 4 at the eutectic point of the second bonding member 9 in the case of containing the bismuth at 58% is 2° ° C. or less.

Therefore, the semiconductor module 50 can be mounted on the metal base plate 1 using the tin solder having a relatively low melting point. This makes it possible to suppress the remelting of the first bonding member 10 inside the semiconductor module 50.

Since the metal base plate 1, the second bonding member 9, and the semiconductor module 50 are cooled by blowing the cooled reducing gas from above the semiconductor module 50 in the mold package mounting step, it is possible to uniformly cool the semiconductor module 50. It is also possible to suppress oxidation of each part of the semiconductor module 50.

### Second Preferred Embodiment

(Structure of semiconductor device)

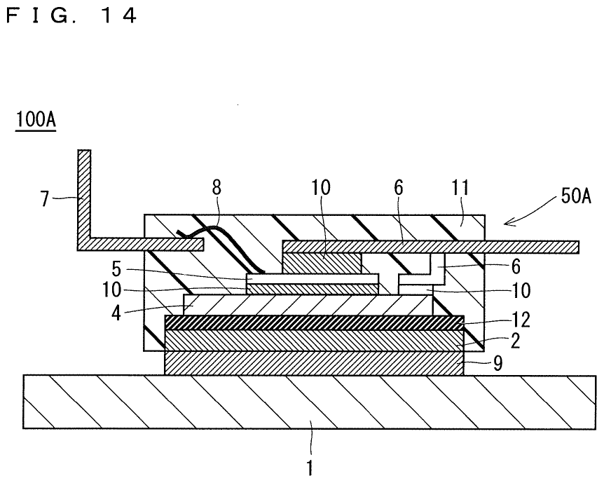

Next, a semiconductor device 100A according to a second preferred embodiment will be described. FIG. 14 is a cross-sectional view of the semiconductor device 100A according to the second preferred embodiment. In the second preferred embodiment, the same components as those described in the first preferred embodiment are denoted by the same reference numerals, and description thereof is omitted.

As illustrated in FIG. 14, in the second preferred embodiment, a ceramic insulating substrate 12 (corresponding to the insulating layer) is provided instead of the resin insulating layer 3 of the first preferred embodiment.

The first metal plate 4 is bonded to an upper surface of the ceramic insulating substrate 12. The second metal plate 2 is bonded to a lower surface of the ceramic insulating substrate 12. The mold resin 11 seals the first metal plate 4, the ceramic insulating substrate 12, the second metal plate 2, the semiconductor element 5, one end sides of the two main terminals 6, and one end sides of the three signal terminals 7 in a state in which the lower surface of the second metal plate 2 is exposed.

<Method of Manufacturing Semiconductor Device>

A method of manufacturing the semiconductor device 100A is the same as that in the first preferred embodiment except that the semiconductor element 5 is die-bonded to the first metal plate 4 bonded to the upper surface of the ceramic insulating substrate 12, and only the wire bonding completed product is set in the cavity of the metal mold at the time of transfer molding.

It is desirable that the first metal plate 4 has a certain thickness in order to spread heat from the semiconductor element 5 as in the first preferred embodiment. Typically, the first metal plate 4 is attached to the ceramic insulating substrate 12, and an unnecessary portion is removed by etching. Thus, if the first metal plate 4 is too thick, it is difficult to manufacture a semiconductor module 50A. Therefore, the thickness of the first metal plate 4 is desirably from 0.5 mm to 0.8 mm, inclusive.

The ceramic insulating substrate 12 has similar functions to the resin insulating layer 3 of the first preferred embodiment, and is desirably made thin for heat dissipation while securing necessary dielectric strength. However, the ceramic insulating substrate 12, which is a brittle material, is also required to have strength against cracking. Therefore, the ceramic insulating substrate 12 is most suitably made of silicon nitride, and the thickness is desirably from 0.25 mm to 0.35 mm, inclusive.

Since the second metal plate 2 as well as the first metal plate 4 is bonded to the ceramic insulating substrate 12 by a brazing material under high temperature, the second metal plate 2 is required to have the same thickness as the first metal plate 4 in order to suppress a warp after bonding.

As in the first preferred embodiment, it is desirable that the metal base plate 1 has a thickness of from 2 mm to 4 mm, inclusive, and is formed of copper, aluminum, or an alloy containing copper or alloy as a main component.

### <Effects>

As described above, the manufacturing method of the second preferred embodiment includes: the transfer molding step of manufacturing the semiconductor module 50A by sealing, with the mold resin 11, the first metal plate 4, the ceramic insulating substrate 12 bonded to the lower surface of the first metal plate 4, the second metal plate 2 bonded to the lower surface of the ceramic insulating substrate 12, and the semiconductor element 5 mounted on the upper surface of the first metal plate 4 with the first bonding member 10 therebetween in a state in which the lower surface of the second metal plate 2 is exposed; and the mold package mounting step of mounting the semiconductor module 50A on the metal base plate 1 by bonding the lower surface of the second metal plate 2 to the upper surface of the metal base plate 1 by the second bonding member 9 having a melting point lower than that of the first bonding member 10. The mold package mounting step includes steps of disposing the semiconductor module 50A on the upper surface of the metal base plate 1 with the second bonding member 9 therebetween, heating the metal base plate 1, the second bonding member 9, and the semiconductor module 50A to melt the second bonding member 9, and then cooling the metal base plate 1, the second bonding member 9, and the semiconductor module 50A to cure the second bonding member 9. During the cooling of the metal base plate 1, the second bonding member 9, and the semiconductor module 50A, the difference between the upper surface temperature of the metal base plate 1 and the lower surface temperature of the first metal plate 4 at the solid phase line of the second bonding member 9 is 5° C. or less.

In the second preferred embodiment, the ceramic insulating substrate 12 does not peel by shearing stress unlike the resin insulating layer 3 of the first preferred embodiment.

However, when the second bonding member 9 solidifies in a state in which the metal base plate 1 is cooled and shrunk earlier than the first metal plate 4 during the cooling in the mold package mounting step, the subsequently-cooled first metal plate 4 shrinks to be warped. The warp applies bending stress to the ceramic insulating substrate 12, which is a brittle material, possibly resulting in cracking. Therefore, by reducing the difference between the upper surface temperature of the metal base plate 1 and the lower surface temperature of the first metal plate 4 during the cooling, residual stress in the mold package mounting step can be reduced. As a result, the warp of the first metal plate 4 can be suppressed, and the cracking of the ceramic insulating substrate 12 can be suppressed. In addition, durability of a cooling/heating cycle in the semiconductor device 100A is improved, so that long-term reliability of the semiconductor device 100A is improved as well.

The second bonding member 9 is the tin solder containing the bismuth. During the cooling of the metal base plate 1, the second bonding member 9, and the semiconductor module 50A, the difference between the upper surface temperature of the metal base plate 1 and the lower surface temperature of the first metal plate 4 at the eutectic point of the second bonding member 9 in the case of containing the bismuth at 58% is 2° C. or less.

Therefore, the semiconductor module 50A can be mounted on the metal base plate 1 using the tin solder having a relatively low melting point. This makes it possible to suppress the remelting of the first bonding member 10 inside the semiconductor module 50A.

Since the metal base plate 1, the second bonding member 9, and the semiconductor module 50A are cooled by blowing the cooled reducing gas from above the semiconductor module 50A in the mold package mounting step, it is possible to uniformly cool the semiconductor module 50A. It is also possible to suppress oxidation of each part of the semiconductor module 50A.

### Third Preferred Embodiment

(Structure of semiconductor device)

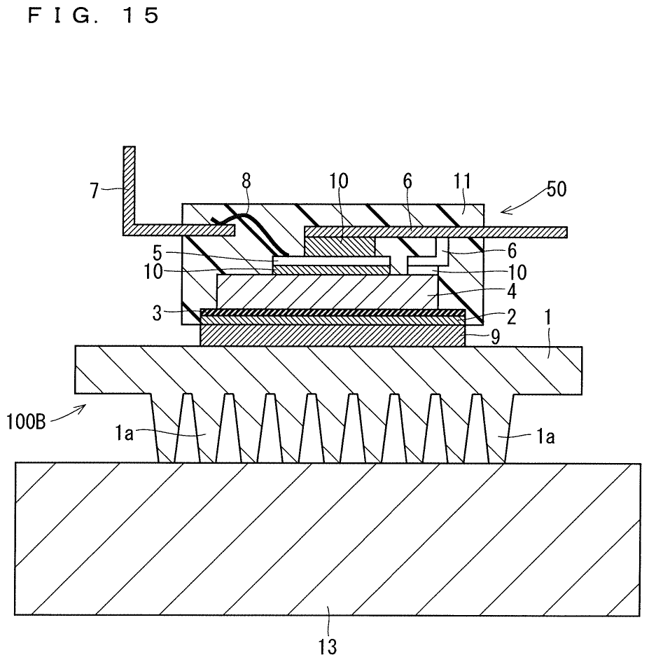

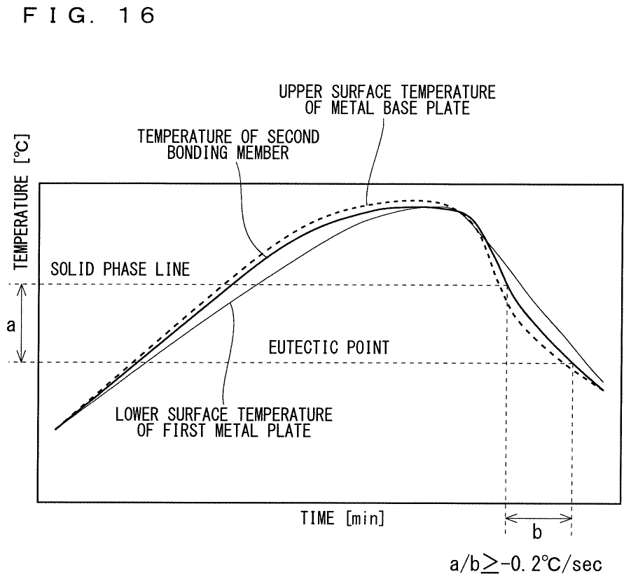

Next, a semiconductor device 100B according to a third preferred embodiment will be described. FIG. 15 is a cross-sectional view of the semiconductor device 100B according to the third preferred embodiment. FIG. 16 is a graph illustrating a difference between an upper surface temperature of the metal base plate 1 and a lower surface temperature of the first metal plate 4 during cooling in the third preferred embodiment. In the third preferred embodiment, the same components as those described in the first and second preferred embodiments are denoted by the same reference numerals, and description thereof is omitted.

As illustrated in FIG. 15, in the third preferred embodiment, a plurality of pin fins 1a protruding downward are provided on the lower surface of the metal base plate 1 as compared with the first preferred embodiment.

<Method of manufacturing semiconductor device>

As illustrated in FIG. 15, a method of manufacturing the semiconductor device 100B is different from that of the first preferred embodiment in that a cooling block 13 is disposed below the metal base plate 1. In the mold package mounting step, the metal base plate 1, the second bonding member 9, and the semiconductor module 50 are cooled by bringing the cooling block 13 into contact with tips of the plurality of pin fins 1a without blowing a reducing gas.

As described above, the temperature control during cooling is necessary in the mold package mounting step. When the semiconductor module 50 is mounted on the upper surface of the metal base plate 1 provided with the plurality of pin fins 1a on the lower surface, it is not possible to perform rapid cooling by bringing the cooling block 13 into contact with the tips of the pin fins 1a. This makes it easy or unnecessary to perform the temperature control for reducing the difference between the upper surface temperature of the metal base plate 1 and the lower surface temperature of the first metal plate 4.

That is, the temperature control becomes easy or unnecessary with regard to setting of the difference between the upper surface temperature of the metal base plate 1 and the lower surface temperature of the first metal plate 4 at the solid phase line of the second bonding member 9 to 5° C. or less during the cooling of the metal base plate 1, the second bonding member 9, and the semiconductor module 50, and setting of the difference between the upper surface temperature of the metal base plate 1 and the lower surface temperature of the first metal plate 4 at the eutectic point of the second bonding member 9 in the case of containing the bismuth at 58% to 2° C. or less during the cooling of the metal base plate 1, the second bonding member 9, and the semiconductor module 50. The same applies to a case where the metal base plate 1 provided with the plurality of pin fins 1a is adopted in the semiconductor device 100A of the second preferred embodiment.

### Modification of Third Preferred Embodiment

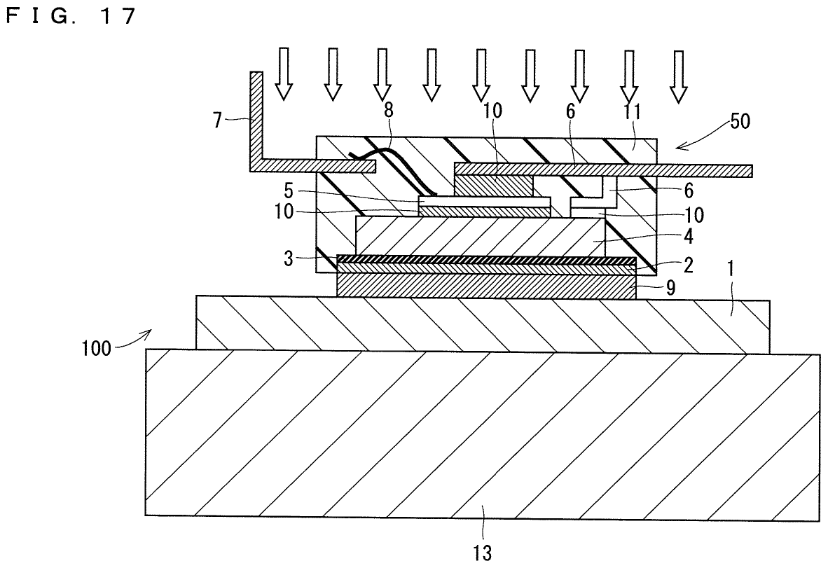

Next, a modification of the third preferred embodiment will be described. FIG. 17 is a cross-sectional view illustrating a part of a method of manufacturing the semiconductor device 100 according to the modification of the third preferred embodiment.

As illustrated in FIG. 17, the modification of the third preferred embodiment will be described using the semiconductor device 100 according to the first preferred embodiment.

In the above description, the defects of the resin insulating layer 3, the ceramic insulating substrate 12, and the second bonding member 9 are suppressed by lowering the cooling rate. However, as a harmful effect caused by lowering the cooling rate, there is a concern that processing time increases and sink marks are generated in the second bonding member 9. The sink marks of the second bonding member 9 tend to be generated when it takes time for the second bonding member 9 to completely solidify after starting to solidify at the time of cooling. This is because a volume of the second bonding member 9 at a position where the second bonding member 9 finally solidifies is insufficient due to volumetric shrinkage at the time of solidification of the second bonding member 9.

Therefore, by rapidly cooling the entire second bonding member 9, the generation of sink marks in the second bonding member 9 can be suppressed. As illustrated in FIG. 16, during the cooling of the metal base plate 1, the second bonding member 9, and the semiconductor module 50, a temperature gradient a/b from the solid phase line of the second bonding member 9 to the eutectic point of the second bonding member 9 in the case of containing the bismuth at 58% is set to an inclination of −0.2° C./see or more, so that the generation of sink marks in the second bonding member 9 can be suppressed.

Therefore, as illustrated in FIG. 17, in the method of manufacturing the semiconductor device 100, the cooling block 13 is brought into contact with the lower surface of the metal base plate 1, and a cooled reducing gas is blown from above the semiconductor module 50 to cool the metal base plate 1, the second bonding member 9, and the semiconductor module 50 in the mold package mounting step. That is, the metal base plate 1 is rapidly cooled by the cooling block 13 from the lower surface of the metal base plate 1, and the first metal plate 4 is also rapidly cooled by blowing the cooled reducing gas from above the semiconductor module 50. As a result, it is possible to suppress the defects of the resin insulating layer 3 and the second bonding member 9, and to suppress the generation of sink marks in the second bonding member 9. Similar effects can be obtained in a case where the modification of the third preferred embodiment is adopted for the semiconductor device 100A of the second preferred embodiment.

However, it is also satisfied in the case of FIG. 17 that the difference between the upper surface temperature of the metal base plate 1 and the lower surface temperature of the first metal plate 4 at the solid phase line of the second bonding member 9 is set to 5° ° C. or less during the cooling of the metal base plate 1, the second bonding member 9, and the semiconductor module 50, and the difference between the upper surface temperature of the metal base plate 1 and the lower surface temperature of the first metal plate 4 at the eutectic point of the second bonding member 9 in the case of containing the bismuth at 58% is set to 2° C. or less during the cooling of the metal base plate 1, the second bonding member 9, and the semiconductor module 50.

### <Effects>

As described above, in the manufacturing method of the third preferred embodiment, the plurality of pin fins 1a protruding downward are provided on the lower surface of the metal base plate 1, and the cooling block 13 is brought into contact with the tips of the plurality of pin fins 1a to cool the metal base plate 1, the second bonding member 9, and the semiconductor module 50 in the mold package mounting step.

Therefore, by passing heat through the pin fins 1a, a heat transfer path can be reduced to reduce a temperature distribution due to rapid cooling, and the shearing stress applied to the resin insulating layer 3 can be suppressed. This makes it possible to suppress breakage of the resin insulating layer 3.

In the manufacturing method of the modification of the third preferred embodiment, the second bonding member 9 is the tin solder containing the bismuth. During the cooling of the metal base plate 1, the second bonding member 9, and the semiconductor module 50, the temperature gradient from the solid phase line of the second bonding member 9 to the eutectic point of the second bonding member 9 in the case of containing the bismuth at 58% is the inclination of −0.2° C./see or more. Therefore, the generation of sink marks in the second bonding member 9 can be suppressed.

In the mold package mounting step, the cooling block 13 is brought into contact with the lower surface of the metal base plate 1, and the cooled reducing gas is blown from above the semiconductor module 50 to cool the metal base plate 1, the second bonding member 9, and the semiconductor module 50.

Therefore, it is possible to suppress the defects of the resin insulating layer 3 and the second bonding member 9, and to suppress the generation of sink marks in the second bonding member 9. It is also possible to suppress oxidation of each part of the semiconductor module 50.

Note that the preferred embodiments can be freely combined, and the preferred embodiments can be modified or omitted as appropriate.

Hereinafter, various aspects of the present disclosure will be collectively described as appendices.

(Appendix 1)

A method of manufacturing a semiconductor device, the method comprising: a step (a) of manufacturing a semiconductor module by sealing, with a mold resin, a first metal plate, an insulating layer bonded to a lower surface of the first metal plate, a second metal plate bonded to a lower surface of the insulating layer, and a semiconductor element mounted on an upper surface of the first metal plate with a first bonding member between the semiconductor element and the first metal plate in a state in which a lower surface of the second metal plate is exposed; and a step (b) of mounting the semiconductor module on a metal base plate by bonding the lower surface of the second metal plate to an upper surface of the metal base plate by a second bonding member having a melting point lower than a melting point of the first bonding member, wherein
the step (b) includes steps of disposing the semiconductor module on the upper surface of the metal base plate with the second bonding member between the semiconductor module and the metal base plate, heating the metal base plate, the second bonding member, and the semiconductor module to melt the second bonding member, and then cooling the metal base plate, the second bonding member, and the semiconductor module to cure the second bonding member, and
during the cooling of the metal base plate, the second bonding member, and the semiconductor module, a difference between an upper surface temperature of the metal base plate and a lower surface temperature of the first metal plate at a solid phase line of the second bonding member is 5° C. or less.

(Appendix 2)

The method of manufacturing a semiconductor device according to appendix 1, wherein
the second bonding member is tin solder containing bismuth, and
during the cooling of the metal base plate, the second bonding member, and the semiconductor module, a difference between an upper surface temperature of the metal base plate and a lower surface temperature of the first metal plate at a cutectic point of the second bonding member in a case of containing the bismuth at 58% is 2° ° C. or less.

(Appendix 3)

The method of manufacturing a semiconductor device according to appendix 1 or 2, wherein in the step (b), the metal base plate, the second bonding member, and the semiconductor module are cooled by blowing a cooled reducing gas from above the semiconductor module.

(Appendix 4)

The method of manufacturing a semiconductor device according to appendix 1 or 2, wherein
a plurality of pin fins protruding downward are provided on a lower surface of the metal base plate, and
in the step (b), the metal base plate, the second bonding member, and the semiconductor module are cooled by bringing a cooling block into contact with tips of the plurality of pin fins.

(Appendix 5)

The method of manufacturing a semiconductor device according to any one of appendices 1 to 3, wherein
the second bonding member is tin solder containing bismuth, and
during the cooling of the metal base plate, the second bonding member, and the semiconductor module, a temperature gradient from the solid phase line of the second bonding member to a eutectic point of the second bonding member in a case of containing the bismuth at 58% is an inclination of −0.2° C./see or more.

(Appendix 6)

The method of manufacturing a semiconductor device according to appendix 5, wherein in the step (b), the metal base plate, the second bonding member, and the semiconductor module are cooled by bringing a cooling block into contact with a lower surface of the metal base plate, and blowing the cooled reducing gas from above the semiconductor module.

While the disclosure has been shown and described in detail, the foregoing description is in all aspects illustrative and not restrictive. It is therefore understood that numerous modifications and variations can be devised.

What is claimed is:

1. A method of manufacturing a semiconductor device, the method comprising:
a step (a) of manufacturing a semiconductor module by sealing, with a mold resin, a first metal plate, an insulating layer bonded to a lower surface of the first metal plate, a second metal plate bonded to a lower surface of the insulating layer, and a semiconductor element mounted on an upper surface of the first metal plate with a first bonding member between the semiconductor element and the first metal plate in a state in which a lower surface of the second metal plate is exposed; and
a step (b) of mounting the semiconductor module on a metal base plate by bonding the lower surface of the second metal plate to an upper surface of the metal base plate by a second bonding member having a melting point lower than a melting point of the first bonding member, wherein
the step (b) includes steps of disposing the semiconductor module on the upper surface of the metal base plate with the second bonding member between the semiconductor module and the metal base plate, heating the metal base plate, the second bonding member, and the semiconductor module to melt the second bonding member, and then cooling the metal base plate, the second bonding member, and the semiconductor module to cure the second bonding member, and
during the cooling of the metal base plate, the second bonding member, and the semiconductor module, a difference between an upper surface temperature of the metal base plate and a lower surface temperature of the first metal plate at a solid phase line of the second bonding member is 5° C. or less.

2. The method of manufacturing a semiconductor device according to claim 1, wherein
the second bonding member is tin solder containing bismuth, and
during the cooling of the metal base plate, the second bonding member, and the semiconductor module, a difference between an upper surface temperature of the metal base plate and a lower surface temperature of the first metal plate at a eutectic point of the second bonding member in a case of containing the bismuth at 58% is 2° C. or less.

3. The method of manufacturing a semiconductor device according to claim 1, wherein in the step (b), the metal base plate, the second bonding member, and the semiconductor module are cooled by blowing a cooled reducing gas from above the semiconductor module.

4. The method of manufacturing a semiconductor device according to claim 2, wherein in the step (b), the metal base plate, the second bonding member, and the semiconductor module are cooled by blowing a cooled reducing gas from above the semiconductor module.

5. The method of manufacturing a semiconductor device according to claim 1, wherein
a plurality of pin fins protruding downward are provided on a lower surface of the metal base plate, and
in the step (b), the metal base plate, the second bonding member, and the semiconductor module are cooled by bringing a cooling block into contact with tips of the plurality of pin fins.

6. The method of manufacturing a semiconductor device according to claim 2, wherein
a plurality of pin fins protruding downward are provided on a lower surface of the metal base plate, and
in the step (b), the metal base plate, the second bonding member, and the semiconductor module are cooled by bringing a cooling block into contact with tips of the plurality of pin fins.

7. The method of manufacturing a semiconductor device according to claim 1, wherein
the second bonding member is tin solder containing bismuth, and
during the cooling of the metal base plate, the second bonding member, and the semiconductor module, a temperature gradient from the solid phase line of the second bonding member to a eutectic point of the second bonding member in a case of containing the bismuth at 58% is an inclination of −0.2° C./see or more.

8. The method of manufacturing a semiconductor device according to claim 2, wherein
the second bonding member is tin solder containing bismuth, and
during the cooling of the metal base plate, the second bonding member, and the semiconductor module, a temperature gradient from the solid phase line of the second bonding member to a eutectic point of the second bonding member in a case of containing the bismuth at 58% is an inclination of −0.2° C./see or more.

9. The method of manufacturing a semiconductor device according to claim 3, wherein
the second bonding member is tin solder containing bismuth, and
during the cooling of the metal base plate, the second bonding member, and the semiconductor module, a temperature gradient from the solid phase line of the second bonding member to a eutectic point of the second bonding member in a case of containing the bismuth at 58% is an inclination of −0.2° C./see or more.

10. The method of manufacturing a semiconductor device according to claim 4, wherein
the second bonding member is tin solder containing bismuth, and
during the cooling of the metal base plate, the second bonding member, and the semiconductor module, a temperature gradient from the solid phase line of the second bonding member to a eutectic point of the second bonding member in a case of containing the bismuth at 58% is an inclination of −0.2° C./see or more.

11. The method of manufacturing a semiconductor device according to claim 7, wherein in the step (b), the metal base plate, the second bonding member, and the semiconductor module are cooled by bringing a cooling block into contact with a lower surface of the metal base plate, and blowing a cooled reducing gas from above the semiconductor module.

12. The method of manufacturing a semiconductor device according to claim 8, wherein in the step (b), the metal base plate, the second bonding member, and the semiconductor module are cooled by bringing a cooling block into contact with a lower surface of the metal base plate, and blowing a cooled reducing gas from above the semiconductor module.

13. The method of manufacturing a semiconductor device according to claim 9, wherein in the step (b), the metal base plate, the second bonding member, and the semiconductor module are cooled by bringing a cooling block into contact with a lower surface of the metal base plate, and blowing the cooled reducing gas from above the semiconductor module.

14. The method of manufacturing a semiconductor device according to claim 10, wherein in the step (b), the metal base plate, the second bonding member, and the semiconductor module are cooled by bringing a cooling block into contact with a lower surface of the metal base plate, and blowing the cooled reducing gas from above the semiconductor module.
